(19) United States
(12) Patent Application Publication
(10) Pub. No.: US 2012/0156815 A1
(43) Pub. Date: Jun. 21, 2012

(54) METHOD FOR FABRICATING LIGHT EMITTING DIODE CHIP

(75) Inventors: SHIH-CHENG HUANG, Hukou (TW); PO-MIN TU, Hukou (TW)

(73) Assignee: ADVANCED OPTOELECTRONIC TECHNOLOGY, INC., Hsinchu Hsien (TW)

(21) Appl. No.: 13/207,441

(22) Filed: Aug. 11, 2011

(30) Foreign Application Priority Data
Dec. 20, 2010 (CN) 201010597451.X

(51) Int. Cl. H01L 21/78

(52) U.S. Cl. 438/33; 257/E21.599

(57) ABSTRACT

A method for fabricating an LED chip includes: providing a sapphire substrate with a SiO₂ pattern layer formed on the substrate; forming a lighting structure on the sapphire substrate with the SiO₂ pattern layer; forming grooves in the lighting structure to divide the lighting structure into a number of light emitting regions, the grooves extending to the sapphire substrate and revealing the SiO₂ pattern layer; removing the SiO₂ pattern layer and forming spaces between the lighting structure and the substrate; etching part of the light emitting regions, and then forming electrodes on the light emitting regions; and cutting the sapphire substrate along the grooves to obtain a plurality of LED chips.

### TECHNICAL FIELD

The disclosure generally relates to methods for fabricating light emitting diode chips, and particularly to a method for fabricating light emitting diodes with high lighting efficiency.

### DESCRIPTION OF RELATED ART

In recent years, due to excellent light quality and high luminous efficiency, light emitting diodes (LEDs) have increasingly been used as substitutes for incandescent bulbs, compact fluorescent lamps and fluorescent tubes as a light source of illumination devices.

A conventional LED includes a substrate and a light emitting structure formed on the substrate. However, the light from the light emitting structure will be absorbed by the substrate and converted into thermal energy when travels to the substrate, therefore decreasing the lighting efficiency of the light emitting structure.

Therefore, a method for fabricating an LED chip is desired to overcome the above described shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1-FIG. 9 are diagrams schematically showing the process of a method for fabricating an LED chip according to a first embodiment of the present disclosure.

FIG. 10 is an illustrating view of a sapphire substrate according to a second embodiment of the present disclosure.

### DETAILED DESCRIPTION

An embodiment for fabricating an LED chip will now be described in detail below and with reference to the drawings.

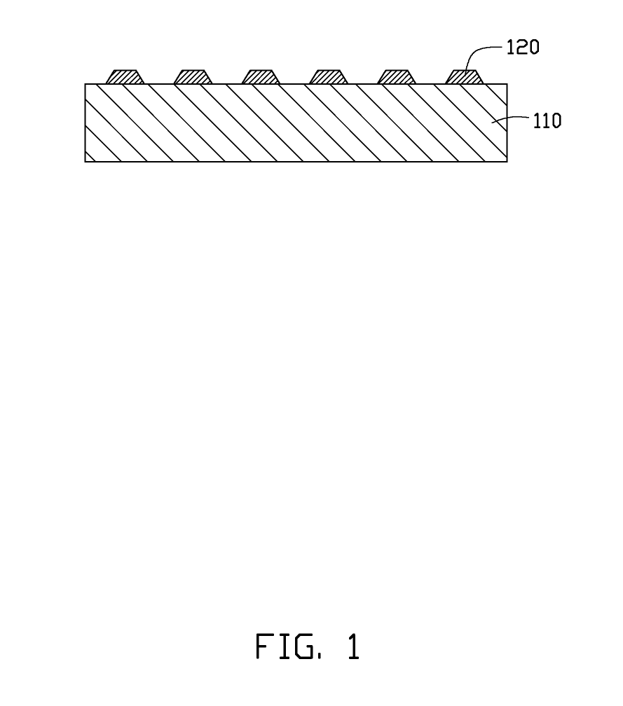

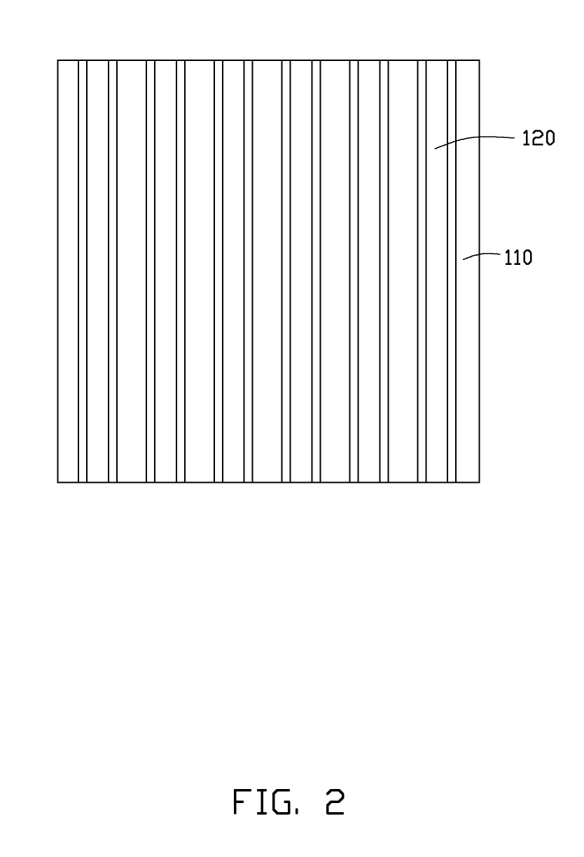

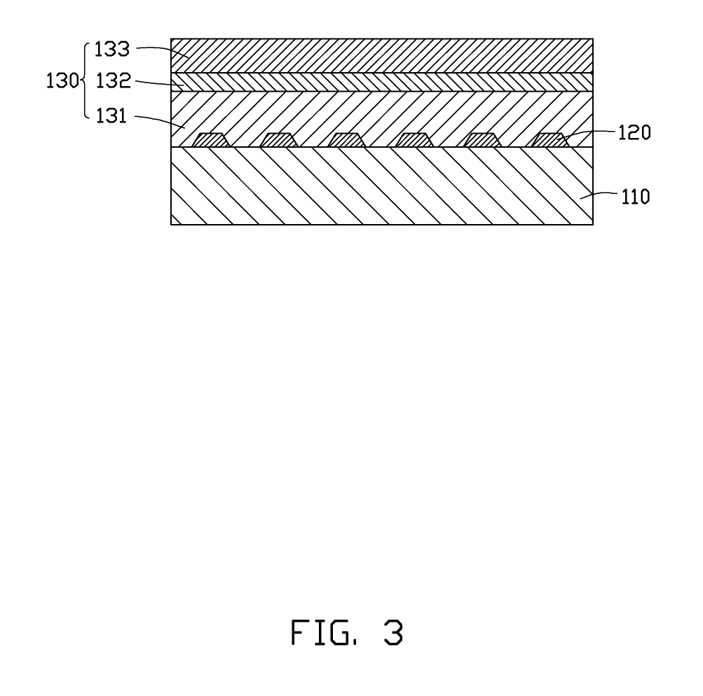

Referring to FIG. 1, a sapphire substrate 110 is provided, and then a SiO₂ pattern layer 120 is formed on the sapphire substrate 110. Further referring to FIG. 2, the SiO₂ pattern layer 120 includes a number of SiO₂ strips paralleled to each other. Referring also to FIG. 3, a cross section of the SiO₂ strips is trapezoid-shaped. In an alternative embodiment, the cross section of the SiO₂ strips can be semicircle-shaped.

Referring to FIG. 3, a light emitting structure 130 is formed on an outer surface of the sapphire substrate 110 with the SiO₂ pattern layer 120, by metal organic chemical vapor deposition (MOCVD) or molecular beam epitaxy (MBE). The light emitting structure 130 includes a n-type GaN layer 131, a multiple quantum well (MQW) layer 132 and a p-type GaN layer 133 formed subsequently in a direction away from the sapphire substrate 110.

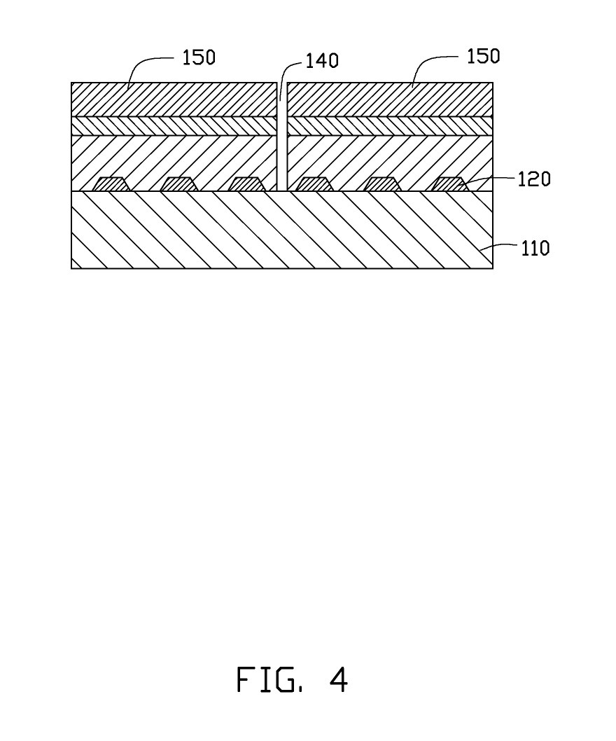

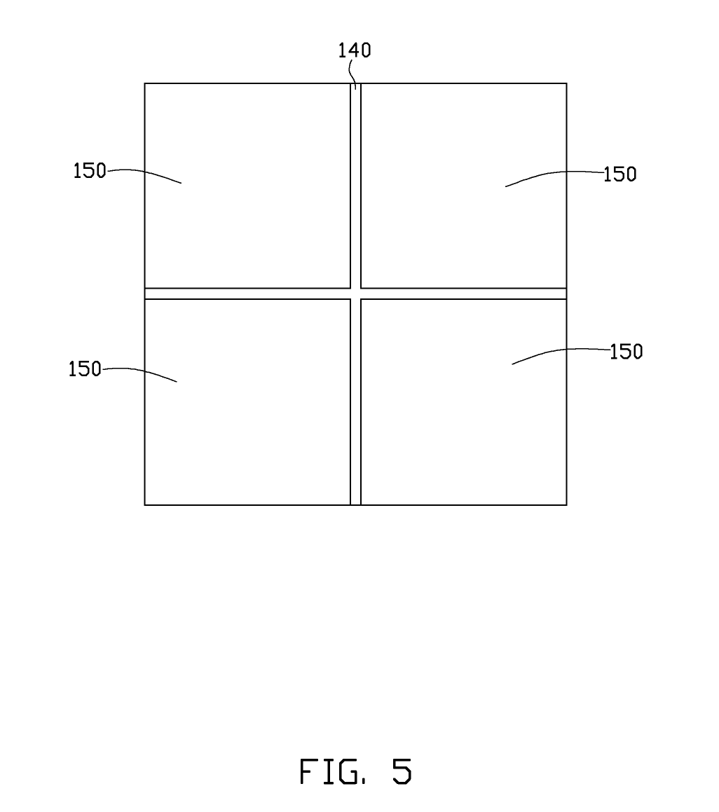

Referring to FIG. 4, grooves 140 are formed on the lighting structure 130 by dry etching to divide the lighting structure 130 into a number of light emitting regions 150. The grooves 140 extend from an upper surface of the lighting structure 130 to the sapphire substrate 110 and reveal part of the SiO₂ pattern layer 120. In this embodiment, two grooves 140 intersect each other and divide the lighting structure 130 into four light emitting regions 150, as shown in FIG. 5.

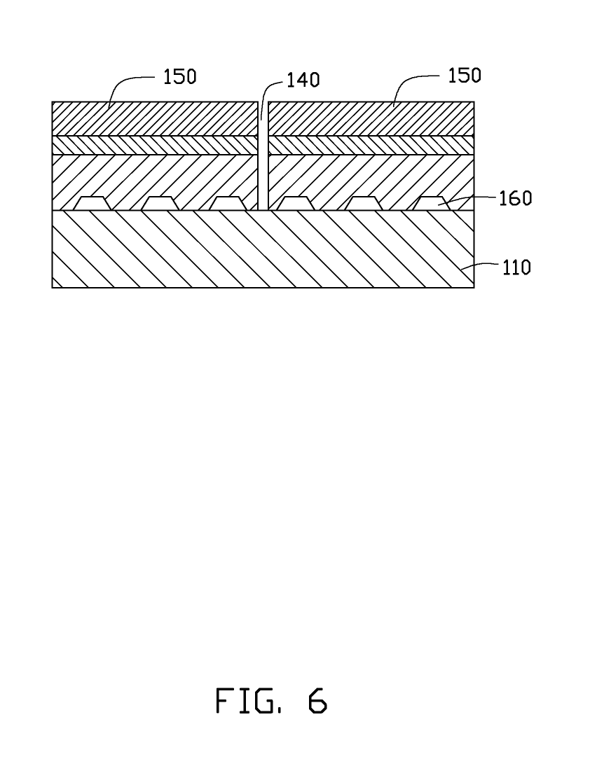

Referring to FIG. 6, the SiO₂ pattern layer 120 is removed by using a buffered oxide etch (BOE) solution. The BOE solution is a mixture of hydrofluoric acid (HF) and ammonium fluoride (NH₄F). The BOE solution can effectively etch the SiO₂ pattern layer 120 when permeating into the grooves 140. After the SiO₂ pattern layer 120 is removed, through holes 160 are formed between the lighting structure 130 and the sapphire substrate 110.

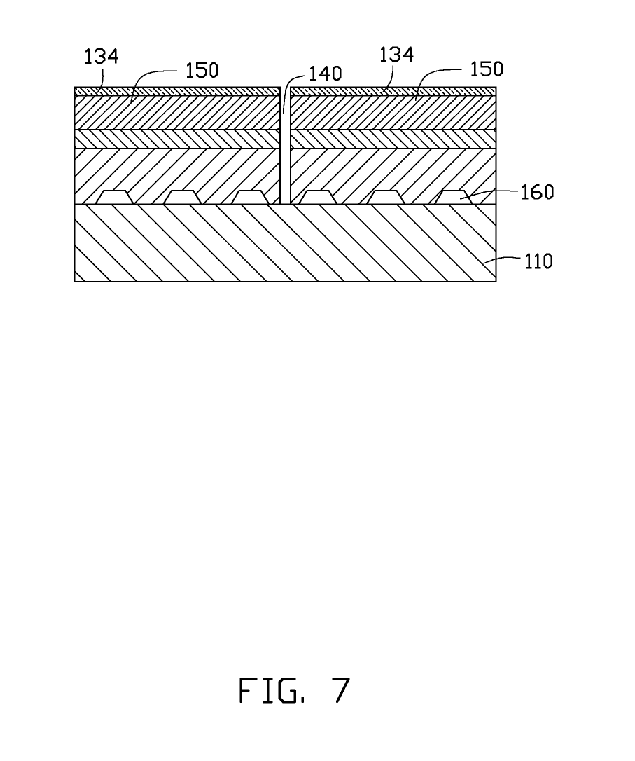

Referring to FIG. 7, after the etching of the SiO₂ pattern layer 120 is finished, an indium-tin oxide (ITO) transparent conductive layer 134 is formed on a surface of the light emitting regions 150. The ITO transparent conductive layer 134 can improve the current diffusion on the surface of the light emitting regions 150.

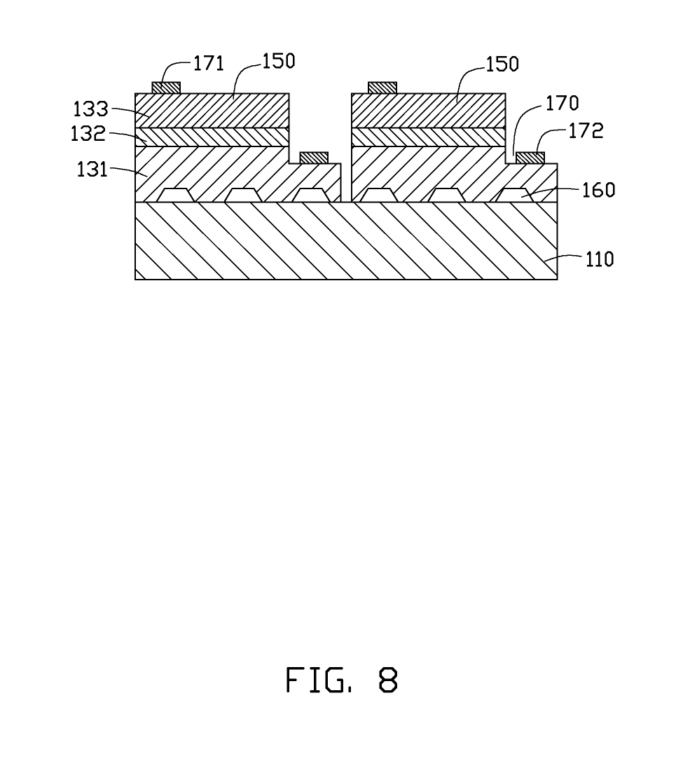

Referring to FIG. 8, part of the light emitting regions 150 are etched to expose part surface of the n-type GaN layer 131 as an electrode supporting platform 170. A p-type electrode 171 and an n-type electrode 172 are then formed on the p-type GaN layer 133 and the electrode supporting platform 170 (i.e. the exposed surface of the n-type GaN layer 131), respectively. The p-type electrode 171 and the n-type electrode 172 can be formed by vacuum evaporation or sputtering. Materials of the p-type electrode 171 and the n-type electrode 172 can be selected from a group consisting of Ti, Al, Ag, Ni, W, Cu, Pd, Cr, Au and alloy thereof.

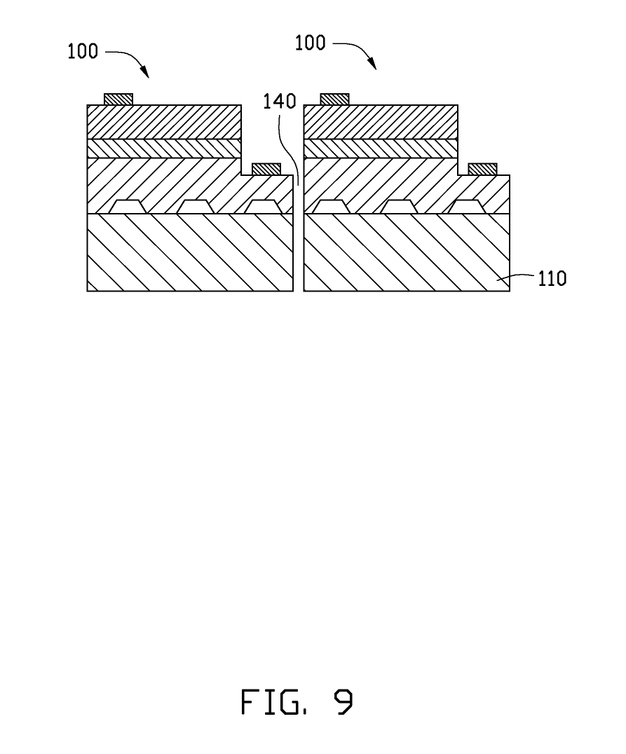

Referring to FIG. 9, the sapphire substrate 110 is cut along the grooves 140 by laser cutting or mechanical cutting and a number of LED chips 110 are obtained.

When a voltage is applied between the p-type electrode 171 and the n-type electrode 172, hole-electron capture will happen at the MQW layer 132, and energy is released in the form of light. When the light from the MQW layer 132 travels to the sapphire substrate 110, the light will be totally reflected back by inclined sidewalls of the through holes 160 and successively travels to outer environment through the p-type GaN layer 133. That is, the through holes 160 between the lighting structure 130 and the sapphire substrate 110 can reduce light being absorbed by the sapphire substrate 110, and improve the lighting efficiency of the LED chip 100.

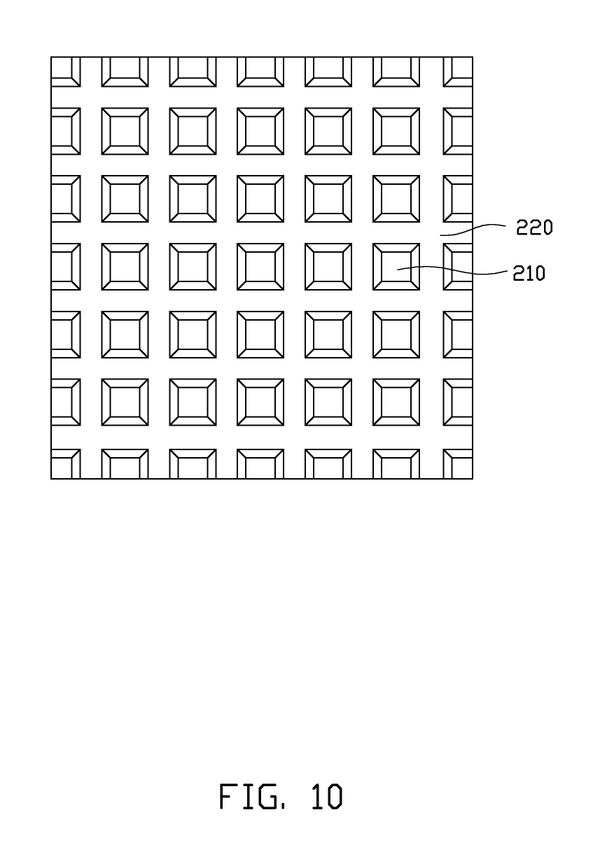

The SiO₂ pattern layer is not limited to the SiO₂ strips parallel to each other. Referring to FIG. 10, a SiO₂ pattern layer 220 in accordance with a second embodiment is formed on a surface of a sapphire substrate 210. The SiO₂ pattern layer 220 includes SiO₂ blocks arranged as a grid structure. The sapphire substrate 210 and the SiO₂ pattern layer 220 can replace the sapphire substrate 110 and the SiO₂ pattern layer 120 in the first embodiment.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A method for fabricating an LED chip, comprising:
providing a sapphire substrate with a SiO₂ pattern layer formed on the substrate;
forming a lighting structure on the sapphire substrate with the SiO₂ pattern layer;
forming grooves in the lighting structure to divide the lighting structure into a number of light emitting regions, the grooves extending to the sapphire substrate and revealing the SiO₂ pattern layer;
removing the SiO₂ pattern layer and forming spaces between the lighting structure and the substrate;
etching part of the light emitting regions, and then forming electrodes on the light emitting regions; and
cutting the sapphire substrate along the grooves to obtain a plurality of LED chips.

2. The method for fabricating an LED chip of claim 1, wherein the SiO₂ pattern layer comprises a plurality of SiO₂ strips paralleled to each other.

3. The method for fabricating an LED chip of claim 1, wherein the SiO₂ pattern layer comprises a plurality of SiO₂ blocks arranged as a grid structure.

4. The method for fabricating an LED chip of claim 2, wherein the cross sections of the SiO₂ strips along the length direction of the strips are trapezoid-shaped.

5. The method for fabricating an LED chip of claim 1, wherein the SiO₂ pattern layer is removed by BOE solution.

6. The method for fabricating an LED chip of claim 5, wherein the BOE solution is a mixture of hydrofluoric acid (HF) and ammonium fluoride (NH₄F).

7. The method for fabricating an LED chip of claim 1, wherein the light emitting structure comprises an n-type GaN layer, a MQW layer and a p-type GaN layer formed subsequently in a direction away from the sapphire substrate.

8. The method for fabricating an LED chip of claim 7, wherein an ITO transparent conductive layer is further formed on the p-type GaN layer before etching part of the light emitting regions.

9. The method for fabricating an LED chip of claim 7, wherein part of the lighting regions are etched to expose part of the n-type GaN layer as an electrode supporting platform, and then a p-type GaN electrode and an n-type GaN electrode are formed on the p-type GaN layer and the exposed n-type GaN layer respectively.

10. The method for fabricating an LED chip of claim 1, wherein material of the electrode is selected from a group consisting of Ti, Al, Ag, Ni, W, Cu, Pd, Cr, Au and alloy thereof.

11. The method for fabricating an LED chip of claim 1, wherein the grooves are formed in the lighting structure by dry etching.
